(19) United States
(12) Patent Application Publication
(10) Pub. No.: US 2003/0000647 A1
(43) Pub. Date: Jan. 2, 2003

(54) Substrate processing chamber

(75) Inventors: Joseph Yudovsky, Campbell, CA (US); Salvador Umotoy, Antioch, CA (US); Chiliang Chen, Sunnyvale, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/895,036

(22) Filed: Jun. 29, 2001

(51) Int. Cl. C23F 1/00; C23C 16/00

(52) U.S. Cl. 156/345.51; 118/728

(57) ABSTRACT

A chemical vapor deposition (CVD) chamber includes a chamber body which defines a chamber enclosure, and a pedestal mounted in the chamber and adapted to support a substrate during processing. Also included in the processing chamber are substrate lifters adapted to lift the substrate from the pedestal, and an edge ring adapted to shield an edge of the substrate during processing and/or a pumping ring adapted to cover an exhaust channel in the enclosure during processing. A lift plate is adapted to be raised by an actuator. The lift plate contacts a substrate lifter to raise the substrate lifter, and the lift plate also has an extension that extends upwardly from the lift plate. The extension contacts and raises the edge ring and/or the pumping ring simultaneously with actuation of the substrate lifter.

### FIELD OF THE INVENTION

This invention relates to semiconductor manufacturing, and is more particularly concerned with processing chambers in which semiconductor manufacturing processes are performed.

### BACKGROUND OF THE INVENTION

Semiconductor manufacturing typically involves applying a number of processes to a substrate such as a silicon wafer. The processes applied may include depositing a thin film of a metal or other substance on the wafer by chemical vapor deposition (CVD) or physical vapor deposition (PVD). Other processes include etching, annealing, photolithography, etc.

Semiconductor manufacturing processes are generally performed under controlled conditions such as high vacuum in dedicated processing chambers. It is necessary to load a wafer into a processing chamber prior to processing and then to remove the wafer from the chamber after processing. In connection with such operations, a typical chamber has a number of moving parts that aid in loading and unloading the wafer. For example, in a conventional CVD chamber, a heated pedestal is provided to support the wafer during deposition processing. Conventionally, the pedestal is movable in a vertical direction. In a conventional sequence of events, the pedestal is in a lowered position while a robot blade enters the CVD chamber with a wafer. Substrate lifters are raised above the surface of the pedestal to lift the wafer from the robot blade. The robot blade retracts and the substrate lifters are then lowered to place the wafer on the pedestal. Then the pedestal is raised to bring the wafer to a processing position near the top of the processing chamber. During deposition processing, process gas is emitted from the top of the processing chamber via a “showerhead”. The sequence is repeated in reverse to unload the wafer from the CVD chamber after processing.

It would be desirable to reduce the manufacturing cost of semiconductor processing chambers by reducing the number of moving parts employed therein.

### SUMMARY OF THE INVENTION

According to a first aspect of the invention a processing chamber adapted to process a substrate is provided. The chamber includes a chamber body which defines a chamber enclosure, and a pedestal mounted in the chamber enclosure and adapted to support the substrate during processing. Also included in the processing chamber are an edge ring (e.g., a shadow ring or purge ring) adapted to shield an edge of the substrate during processing, and a lift mechanism adapted to selectively raise and lower the edge ring.

The processing chamber may further include a pumping ring adapted to cover an exhaust channel in the enclosure, with the lift mechanism adapted to raise the pumping ring with the edge ring. The processing chamber may further include a substrate lifter (e.g., a lift pin or a lift hoop) adapted to lift the substrate from the pedestal, with the same lift mechanism being adapted to raise the substrate lifter simultaneously with the edge ring and/or the pumping ring.

The lift mechanism may have a first range of movement in which the lift mechanism raises the edge ring and/or the pumping ring without raising the substrate lifter, and a second range of movement in which the lift mechanism simultaneously raises both the substrate lifter and the edge ring and/or pumping ring. The lift mechanism may include a lift plate adapted to actuate the substrate lifter, and an extension extending upwardly from the lift plate and adapted to contact and raise the edge ring.

With a semiconductor processing chamber provided in accordance with the invention, it is possible to avoid the expense of providing a lift mechanism for the pedestal on which a wafer is held during processing. Furthermore, by using a single lift mechanism both to actuate a substrate lifter and to lift an edge ring and/or a pumping ring, the number of moving parts and the cost of the processing chamber are further reduced.

According to another aspect of the invention, there is provided an actuator assembly adapted to be installed on a substrate processing chamber. The actuator assembly includes an assembly housing adapted to be mounted to an underside of the substrate processing chamber. Also included in the actuator assembly is an actuator housing mounted outside a lower end of the assembly housing, the actuator having a plunger that extends upwardly from the actuator into the assembly housing. The actuator assembly further includes a bellows having a first flange at a first end of the bellows and attached to the plunger and having a second flange at a second end of the bellows and attached to the actuator housing.

The actuator assembly provided in accordance with this aspect of the invention may be conveniently assembled prior to installation on the processing chamber, and helps to assure that the actuator plunger is properly aligned relative to the processing chamber.

Other objects, features and advantages of the invention will become more fully apparent from the following detailed description of the exemplary embodiments, the appended claims and the accompanying drawings.

### BRIEF DESCRIPTION OF THE DRAWINGS

FIG. 1 is a side cross-sectional view of a CVD chamber provided in accordance with an aspect of the invention and having an edge ring and a pumping ring positioned for deposition processing;

FIG. 2 is a view similar to FIG. 1, showing a robot blade inserted into the CVD chamber to load or unload a wafer, and with the edge ring and pumping ring in an elevated position;

FIG. 3 is a schematic plan view showing only the edge ring and pumping ring of the CVD chamber of FIGS. 1 and 2;

FIGS. 4A and 4B are an enlarged plan and side view, respectively, showing a point of support for the edge ring and pumping ring; and

FIG. 5 is a side view of a top portion of an extension which lifts the edge ring and pumping ring.

### DETAILED DESCRIPTION OF PREFERRED EMBODIMENTS

In accordance with the invention, a CVD chamber includes a stationary wafer support pedestal. An edge ring rests on the pedestal and protects the edge of a wafer during CVD processing. The edge ring is lifted up from the pedestal when processing is completed to allow exchange of wafers. The same lift mechanism that lifts the edge ring is also employed to actuate a substrate lifter and to lift a pumping ring out of the path of a robot blade. In a first range of movement of the lift mechanism, the edge ring and the pumping ring are lifted but the substrate lifter is not lifted. In a second range of movement above the first range of movement, the lift mechanism simultaneously lifts the edge ring, the pumping ring and the substrate lifter.

A CVD chamber 10 provided in accordance with an aspect of the invention that has a stationary wafer-support pedestal 12, will now be described with reference to the drawings.

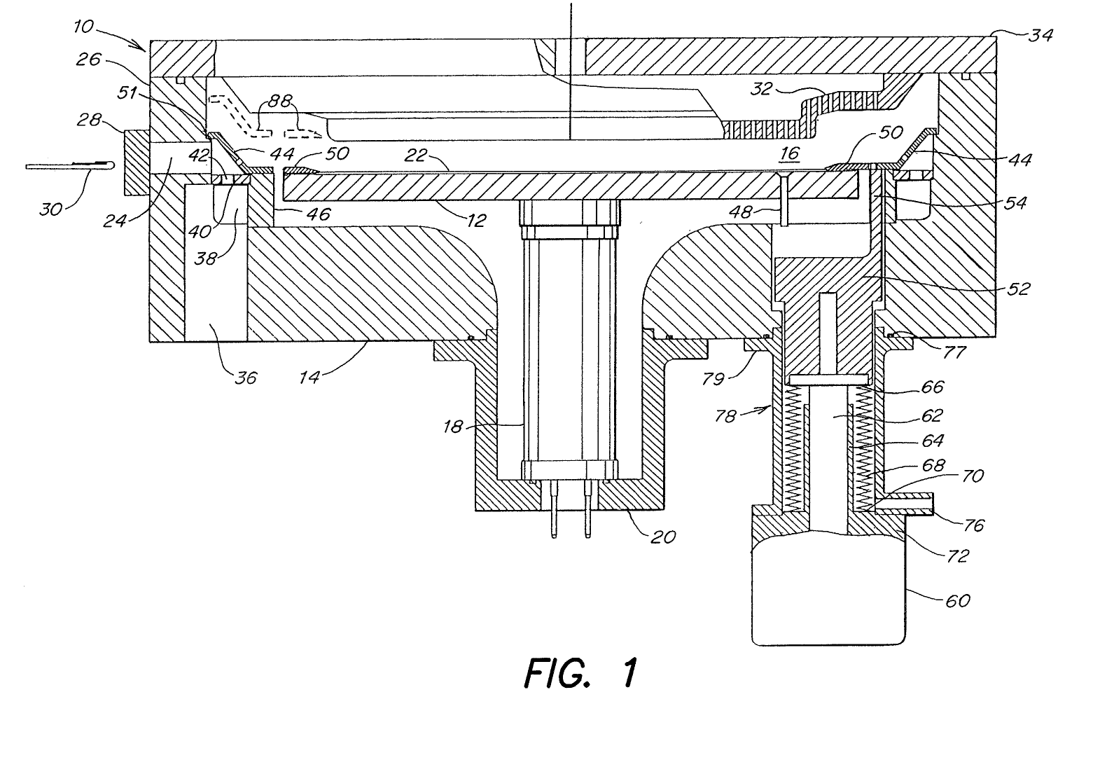

FIG. 1 is a side cross-sectional view of the CVD chamber 10, showing components of the chamber 10 as the same are disposed during deposition processing. As seen from FIG. 1, the chamber 10 includes a chamber body 14 that defines a chamber enclosure 16. In this exemplary aspect the pedestal 12 is fixedly mounted in the chamber enclosure 16 on a shaft 18 which, in turn, is fixedly mounted on a bottom 20 of the chamber body 14. The pedestal 12 may be heated by a coil (not separately shown) and is provided to support a wafer 22 during deposition processing.

A slit 24 is formed in a side wall 26 of the chamber body 14 to allow access to the chamber enclosure 16 for loading and unloading the wafer 22. A slit valve 28 selectively closes the slit 24. A robot blade 30 is shown poised adjacent the slit valve 28.

A showerhead 32 is suspended from the top 34 of the chamber 10. During deposition processing, a process gas flows through the showerhead 32 toward the wafer 22.

An exhaust port 36 formed in the chamber body 14 connects an exhaust pump (not shown) with an exhaust channel 38. The exhaust channel 38 is covered by a first plate 40 having holes 42 formed therein. A pumping ring 44 covers first plate 40 and exhaust channel 38. In accordance with conventional practice, the pumping ring 44 is provided to promote a uniform distribution of exhaust gases in the chamber 10 during deposition processing. (As will be appreciated by those who are skilled in the art, pumping ring 44 has holes formed therein to allow exhaust gases to flow through pumping ring 44 into exhaust channel 38, although the holes are not shown in FIG. 3, which is a somewhat schematic plan view showing only pumping ring 44 and edge ring 50.) A removable liner 46 is installed on the chamber body 14 adjacent the exhaust channel 38.

A substrate lifter such as a plurality of lift pins (of which one pin 48 is shown) is provided to selectively lift the wafer 22 from the pedestal 12.

An edge ring 50 (such as a shadow ring or purge ring) is provided above and at the periphery of the pedestal 12 to shield the edge of the wafer 22 from process gas during deposition processing as is conventionally known. During processing, edge ring 50 is supported on pedestal 12, and pumping ring 44 is supported on liner 46 and on step 51 of side wall 26 of chamber body 14.

A lift plate 52 is provided to selectively actuate substrate lifter 48. Extending upwardly from the lift plate 52 is an extension 54. The extension 54 has a top surface 56 which is positioned slightly below edge ring 50 and pumping ring 44 during processing. On other occasions the top surface 56 of extension 54 contacts the edge ring 50 and the pumping ring 44 at a contact point 58 (FIG. 3) to raise and support pumping ring 44 and edge ring 50.

Continuing to refer to FIG. 1, lift plate 52 is selectively raised and lowered by an actuator 60. In the aspect shown, the actuator 60 has a plunger 62 which moves inside a sleeve 64. The lift plate 52 is mounted on the plunger 62. The plunger 62 is connected to an upper flange 66 of a bellows 68. A lower flange 70 of the bellows 68 is connected to a housing 72 of the actuator 60. A substantially cylindrical assembly housing 74 defines a space within which the actuator 60, the plunger 62 and the lift plate 52 are installed. Assembly housing 74 is substantially concentric with plunger 62. The space inside bellows 68 is at atmospheric pressure, whereas the space between bellows 68 and assembly housing 74 is in the environment of the chamber enclosure 16 and is at low pressure during processing. Purge gas is introduced between assembly housing 74 and bellows 68 via a fitting 76. An O-ring 77 seals the joint between the assembly housing 74 and the chamber body 14.

Assembly housing 74, actuator 60 including plunger 62, sleeve 64 and bellows 68 constitute an actuator assembly that may be pre-assembled prior to installation on the chamber 10. The geometry of assembly housing 74 assures that the plunger 62 of actuator 60 will be properly aligned for vertical movement relative to the chamber body 14 by means of a horizontal flange 79 on the assembly housing that is secured to the bottom of the chamber body 14.

The actuator 60, plunger 62 and lift plate 52 including its extension 54 make up a lift mechanism 78 that both actuates the substrate lifter 48 and selectively raises and lowers the edge ring 50 and the pumping ring 44. Although only one lift mechanism 78 is shown in the drawings, it should be understood that a respective lift mechanism may be provided for each of the plurality of wafer lift pins referred to above. Alternatively, a single lift mechanism may be provided to actuate all of the wafer lift pins (or a wafer lift hoop) and to contact the pumping ring 44 and/or the edge ring 50 at all of the contact points 58 (FIG. 3).

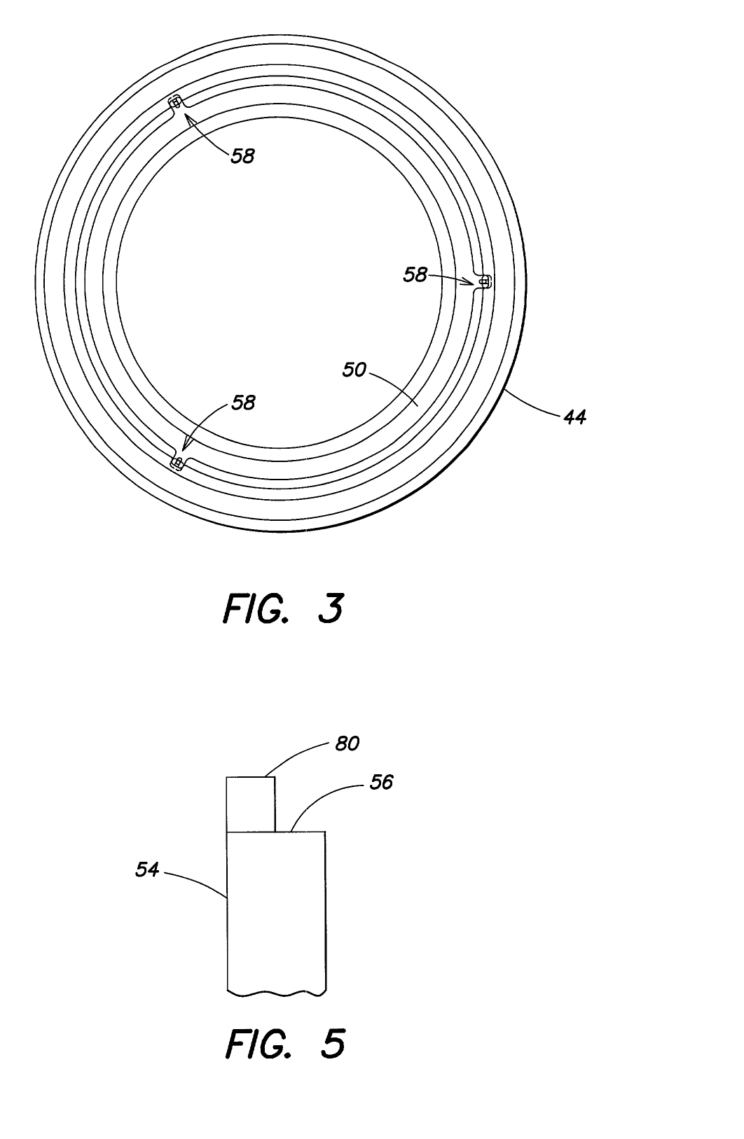

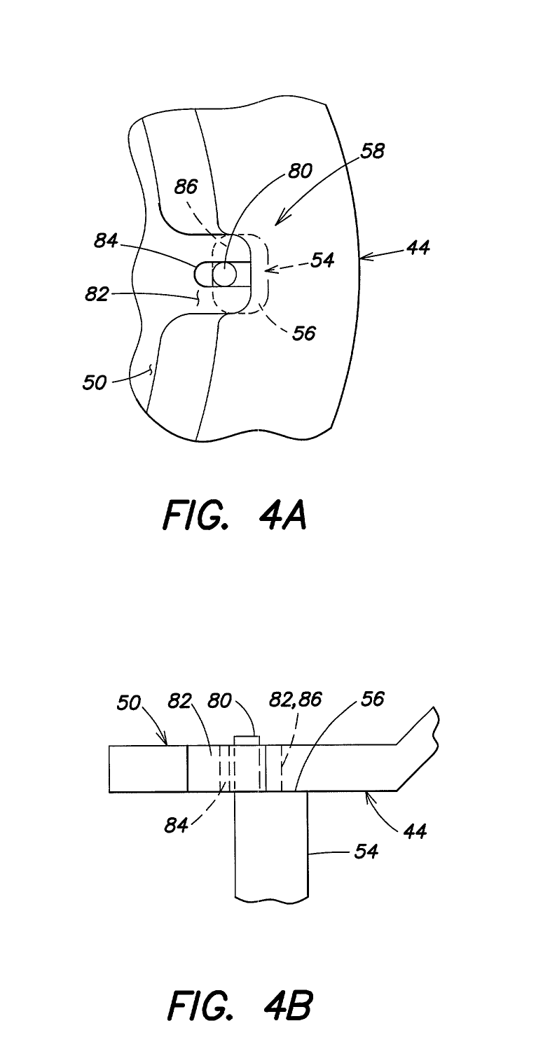

Referring now to FIGS. 4A-B (top plan and side elevation views showing the interface between the edge ring 50 and the pumping ring 44) and FIG. 5 (a side elevational view of the extension 54), the extension 54 has a protrusion 80 that extends upwardly from the top surface 56 of the extension 54. At each point of contact 58 (FIGS. 3 and 4) the edge ring 50 has a horizontally extending tab 82 that includes a slot 84. The protrusion 80 of the extension 54 is received in the slot 84 of the edge ring 50 to properly align the edge ring 50 with respect to the pedestal 12 (FIG. 1). Continuing to refer to FIG. 4, at times when the extension 54 supports edge ring 50 and pumping ring 44, the tab 82 of the edge ring 50 rests on the top surface 56 of the extension 54. At such times, the pumping ring 44 also rests on the top surface 56 of the extension 54. Pumping ring 44 has a recess 86 that allows the tab 82 of the edge ring 50 to share the top surface 56 of the extension 54.

In operation, wafer 22 is supported on pedestal 12 during deposition processing as shown in FIG. 1. Edge ring 50 is positioned to shield the edge of wafer 22 from process gas so that deposition does not occur on the edge of the wafer 22. Pumping ring 44 covers exhaust channel 38. Substrate lifter 48 is retracted at or below the top surface of the pedestal 12, and lift plate 52 is also retracted.

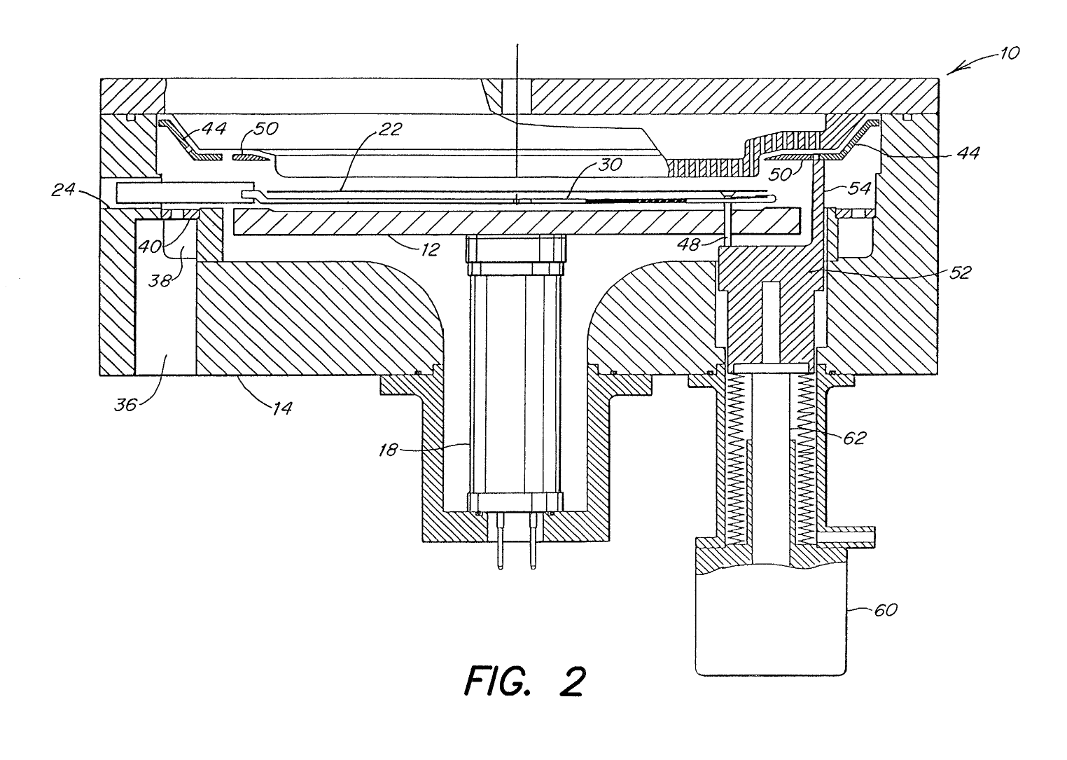

Upon completion of a deposition process, lift plate 52 is raised by actuator 60, to initially raise pumping ring 44 and edge ring 50 via extension 54, and subsequently also to actuate substrate lifter 48 to lift wafer 22 from pedestal 12. Slit valve 28 opens, to allow robot blade 30 to enter the chamber 10. The resulting condition is shown in FIG. 2. In the position shown in FIG. 2, pumping ring 44 and edge ring 50 are fully elevated, and do not obstruct the path of travel of robot blade 30 or interfere with movement of wafer 22.

The lift plate 52 is then lowered to lower the substrate lifter 48 to place wafer 22 on robot blade 30. It will be recognized that simultaneously with the lowering of substrate lifter 48, pumping ring 44 and edge ring 50 are lowered. However, as the substrate lifter 48 lowers, pumping ring 44 and edge ring 50 are not lowered below an intermediate or partially lowered position (indicated in phantom at 88 in FIG. 1) at which pumping ring 44 and edge ring 50 do not interfere with movement of the robot blade 30 and the wafer 22.

After the wafer 22 is deposited on the robot blade 30 by the substrate lifter 48, the robot blade 30 is retracted from the chamber 10 to remove the processed wafer 22. Shortly afterwards, the robot blade 30 again enters the chamber 10, carrying a new wafer to be processed. The lift plate 52 is raised again to raise the substrate lifter 48 to lift the new wafer from the robot blade 30. It will be recognized that pumping ring 44 and shadow blade 50 are raised from their intermediate position 88 (FIG. 1) to the fully elevated position shown in FIG. 2 simultaneously with the raising of substrate lifter 48. Thus the position of FIG. 2 again results, but with a new wafer in place of the processed wafer 22. With the new wafer supported on the substrate lifter 48, the robot blade 30 is again retracted from the chamber 10. Lift plate 52 is then fully lowered, lowering substrate lifter 48 to place the new wafer on the pedestal 12, and continuing to lower lift plate 52 so that the pumping ring 44 and the edge ring 50 are lowered to their processing positions shown in FIG. 1. At the same time, substrate lifter 48 is again completely retracted.

From an examination of FIG. 1, and based on the previous discussion, it will be recognized that the lift mechanism 78 has two ranges of movement, including a first range of movement from the point at which lift plate 52 is fully retracted. In the first range of movement of lift mechanism 78, the pumping ring 44 and the edge ring 50 are lifted by extension 54, but lift plate 52 does not yet contact substrate lifter 48 and therefore does not raise substrate lifter 48. Then, in a second range of movement of the lift mechanism 78 above the first range of movement, pumping ring 44, edge ring 50 and substrate lifter 48 are raised simultaneously by the lift mechanism 78.

In the aspect of the inventive CVD chamber described herein, the heated pedestal 12 is fixedly mounted in the chamber 10. Thus in this aspect there is no need to provide a lift mechanism for the pedestal 12, and the cost of manufacturing the chamber 10 is reduced. Alternatively, or additionally, a single lift mechanism 78 may be provided both to actuate the wafer substrate lifter 48 and to move the pumping ring 44 and the edge ring 50 between a processing position in which pumping ring 44 and edge ring 50 obstruct transfer of the wafer 22, and a retracted position in which the pumping ring 44 and edge ring 50 do not interfere with transfer of the wafer 22. Accordingly, since a single lift mechanism may be used for two or more of the substrate lifter 48, the pumping ring 44 and edge ring 50, the mechanism for the chamber 10 may be simplified and the cost of manufacturing reduced.

The foregoing description discloses only an exemplary embodiment of the invention; modifications of the above-disclosed apparatus and method which fall within the scope of the invention will be readily apparent to those of ordinary skill in the art. For example, the present invention has been described in the context of a CVD chamber, but it is understood that the present invention may have application to other processes, process chambers and apparatuses, such as PVD and etch processes.

Furthermore, as described above, the present invention contemplates using a single lift mechanism to actuate a wafer substrate lifter and to elevate an edge ring and/or a pumping ring where a fixedly mounted pedestal is employed in the processing chamber. However, it is also contemplated to use a single lift mechanism for actuating a wafer substrate lifter and retracting an edge ring and/or a pumping ring even when a moveable pedestal is employed in a processing chamber. It is also contemplated that the lift mechanism used to actuate the wafer substrate lifter may also be used to elevate only an edge ring or a pumping ring.

In the exemplary embodiment disclosed herein, edge ring 50 is adapted to shield an edge of a wafer during CVD processing. However, as the term “shadow ring” is used in the claims, it includes any surface which overlaps a portion of a substrate and protects it from the associated process to which a remaining portion of the substrate is subjected. It specifically includes edge rings and clamp rings associated with PVD, CVD and electroplating processes, while the term “edge ring” includes both shadow rings and purge rings (e.g., rings that protect the edge of a wafer without overlapping the wafer's edge).

Accordingly, while the present invention has been disclosed in connection with preferred embodiments thereof, it should be understood that other embodiments may fall within the spirit and scope of the invention, as defined by the following claims.

The invention claimed is:

1. A processing chamber adapted to process a substrate, comprising:
a chamber body which defines a chamber enclosure;
a pedestal fixedly mounted in the chamber enclosure and adapted to support the substrate during processing;
an edge ring adapted to shield an edge of the substrate during processing;
a lift mechanism adapted to selectively raise and lower the edge ring; and
a substrate lifter adapted to lift the substrate from the pedestal,
wherein the lift mechanism is adapted to raise the substrate lifter simultaneously with the edge ring.

2. The processing chamber of claim 1, wherein the lift mechanism has a first range of movement in which the lift mechanism raises the edge ring without raising the substrate lifter and the lift mechanism has a second range of movement in which the lift mechanism simultaneously raises both the edge ring and the substrate lifter.

3. The processing chamber of claim 2, wherein the second range of movement is above the first range of movement.

4. The processing chamber of claim 2, wherein the lift mechanism includes a lift plate adapted to actuate the substrate lifter, and an extension extending upwardly from the lift plate and adapted to contact the edge ring to raise the edge ring.

5. The processing chamber of claim 1, wherein the pedestal is heated.

6. The processing chamber of claim 1, wherein the chamber is adapted to perform a chemical vapor deposition (CVD) process with respect to the substrate.

7. The processing chamber of claim 1, wherein the lift mechanism moves the edge ring between a processing position in which the edge ring obstructs a path of travel of a robot blade and an elevated position in which the edge ring does not obstruct the path of travel of the robot blade.

8. A processing chamber adapted to process a substrate, comprising:
a chamber body which defines a chamber enclosure;
a pedestal fixedly mounted in the chamber enclosure and adapted to support the substrate during processing;
an edge ring adapted to shield an edge of the substrate during processing;
a lift mechanism adapted to selectively raise and lower the edge ring; and
a pumping plate adapted to cover an exhaust channel in the enclosure;
wherein the lift mechanism raises the pumping plate with the edge ring.

9. A processing chamber adapted to process a substrate, comprising:
a chamber body which defines a chamber enclosure;
a pedestal mounted in the chamber enclosure and adapted to support the substrate during processing;
a substrate lifter adapted to lift the substrate from the pedestal;
an edge ring adapted to shield an edge of the substrate during processing; and
a lift mechanism adapted to simultaneously raise the edge ring while raising the substrate lifter relative to the pedestal.

10. The processing chamber of claim 9, further comprising a pumping plate adapted to cover an exhaust channel in the enclosure, and wherein the lift mechanism raises the pumping plate with the edge ring.

11. The processing chamber of claim 10, wherein the lift mechanism includes a lift plate adapted to actuate the substrate lifter, and an extension that extends upwardly from the lift plate to contact the edge ring and the pumping plate.

12. The processing chamber of claim 11, wherein the edge ring has a tab with a slot formed therein, the slot adapted to engage a protrusion on the extension of the lift plate.

13. A processing chamber adapted to process a substrate, comprising:
a chamber body which defines a chamber enclosure;
a pedestal in the chamber enclosure and adapted to support the substrate during processing;
an edge ring adapted to shield an edge of the substrate during processing; and
a lift mechanism adapted to selectively raise and lower the edge ring, the lift mechanism moving the edge ring between a first position at which the edge ring shields the edge of the substrate during processing and a second position above the first position, the edge ring being held at the second position during loading of the substrate into the chamber enclosure.

14. The processing chamber of claim 13, wherein the edge ring obstructs a path of travel of a robot blade when in the first position and does not obstruct the path of travel of the robot blade when in the second position.

15. The processing chamber of claim 13, further comprising a substrate lifter adapted to lift the substrate from the pedestal, and wherein the lift mechanism is adapted to raise the substrate lifter simultaneously with the edge ring.

16. The processing chamber of claim 13, wherein the lift mechanism includes a lift plate adapted to actuate the substrate lifter, and an extension extending upwardly from the lift plate and adapted to contact the edge ring to raise the edge ring.

17. The processing chamber of claim 13, wherein the pedestal is fixedly mounted in the chamber enclosure.

18. A processing chamber adapted to process a substrate, comprising:
a chamber body which defines a chamber enclosure;
a pedestal mounted in the chamber enclosure and adapted to support the substrate during processing;
a pumping plate adapted to cover an exhaust channel in the enclosure; and
a lift mechanism adapted to selectively raise and lower the pumping plate.

19. The processing chamber of claim 18, further comprising a substrate lifter adapted to lift the substrate from the pedestal, and wherein the lift mechanism is adapted to raise the substrate lifter simultaneously with the pumping plate.

20. The processing chamber of claim 19, wherein the lift mechanism includes a lift plate adapted to actuate the substrate lifter, and an extension extending upwardly from the lift plate and adapted to contact the pumping plate to raise the pumping plate.

21. The processing chamber of claim 18, wherein the lift mechanism moves the pumping plate between a first position at which the pumping plate covers the exhaust channel during processing and a second position that is above the first position, the pumping plate being held at the second position during loading of the substrate into the chamber enclosure.

22. The processing chamber of claim 21, wherein the pumping plate obstructs a path of travel of a robot blade when in the first position and does not obstruct the path of travel of the robot blade when in the second position.

23. A processing chamber adapted to process a substrate, comprising:
a chamber body which defines a chamber enclosure;
a pedestal fixedly mounted in the chamber enclosure and adapted to support the substrate during processing;
a substrate lifter adapted to lift the substrate from the pedestal;
an edge ring adapted to shield an edge of the substrate during processing;
a pumping plate adapted to cover an exhaust channel in the enclosure during processing;
an actuator; and
a lift plate adapted to be raised by the actuator, the lift plate also being adapted to contact the substrate lifter to raise the substrate lifter, the lift plate having an extension that extends upwardly from the lift plate, the extension being adapted to contact and raise the edge ring and the pumping plate.

24. The processing chamber of claim 23, wherein the edge ring has a tab with a slot formed therein, the slot adapted to engage a protrusion on the extension of the lift plate.

25. A method of operating a substrate processing chamber, comprising:
providing a substrate lifter adapted to lift a substrate from a pedestal in the chamber;
providing an edge ring adapted to shield an edge of the substrate during processing;
providing a pumping plate adapted to cover an exhaust channel in the chamber during processing; and
using a lift mechanism to actuate the substrate lifter and to simultaneously raise the edge ring and the pumping plate.

26. A method of operating a substrate processing chamber that includes an edge ring, a pumping ring and a substrate lifter, the method comprising:
moving a lift mechanism in a first range of movement to raise the edge ring and the pumping ring without raising the substrate lifter; and
moving the lift mechanism in a second range of movement to simultaneously raise the edge ring, the pumping ring and the substrate lifter.

27. A processing chamber adapted to process a substrate, comprising:
a chamber body which defines a chamber enclosure;
a pedestal fixedly mounted in the chamber enclosure and adapted to support the substrate during processing;
a substrate lifter adapted to lift the substrate from the pedestal;
an edge ring adapted to shield an edge of the substrate during processing;
a pumping ring adapted to cover an exhaust channel in the enclosure during processing; and
a lift mechanism adapted to (a) move in a first range of movement to simultaneously raise the edge ring and the pumping ring without raising the substrate lifter, and (b) move in a second range of movement to simultaneously raise the edge ring, the pumping ring and the substrate lifter.

28. An actuator assembly adapted to be installed on a substrate processing chamber, comprising:
an assembly housing adapted to be mounted to an underside of the substrate processing chamber;
an actuator mounted at a lower end of the assembly housing, the actuator having a plunger that extends upwardly from the actuator into the assembly housing;
a sleeve in which the plunger moves; and
a bellows having a first flange at a first end of the bellows attached to the plunger and having a second flange at a second end of the bellows attached to the actuator.

29. The actuator assembly of claim 28, wherein the assembly housing is substantially cylindrical, and the plunger is substantially concentric with the assembly housing.

30. The actuator assembly of claim 28, wherein the assembly housing includes a fitting adapted to introduce a purge gas into the assembly housing between the assembly housing and the bellows.
